(19) United States
(12) Patent Application Publication
(10) Pub. No.: US 2016/0329304 A1
(43) Pub. Date: Nov. 10, 2016

(54) SEMICONDUCTOR DEVICE AND METHOD OF MANUFACTURING SEMICONDUCTOR DEVICE

(71) Applicant: PS4 Luxco S.a.r.l., Luxembourg (LU)

(72) Inventors: Koichi Hatakeyama, Tokyo (JP); Youkou Ito, Tokyo (JP)

(21) Appl. No.: 14/889,797

(22) PCT Filed: May 2, 2014
(86) PCT No.: PCT/JP2014/062147

§ 371 Date: Nov. 6, 2015

(30) Foreign Application Priority Data
May 7, 2013 (JP) 2013097424

(51) Int. Cl. H01L 25/065; H01L 23/31; H01L 25/18; H01L 23/544; H01L 25/00; H01L 21/56; H01L 23/00; H01L 23/498

(52) U.S. Cl. CPC H01L 25/0657; H01L 24/17; H01L 23/3128; H01L 23/49838; H01L 23/544; H01L 24/11; H01L 24/81; H01L 25/50; H01L 21/565; H01L 24/97; H01L 21/561; H01L 23/3135; H01L 24/49; H01L 24/32; H01L 24/73; H01L 23/49827; H01L 25/18; H01L 23/3142; H01L 2225/06513; H01L 2225/06517; H01L 2224/16148; H01L 2224/16227; H01L 2224/17181; H01L 2924/1011; H01L 2223/54433; H01L 2225/06555; H01L 2224/81193; H01L 2225/0651; H01L 2224/48091; H01L 2224/48106; H01L 2224/48227; H01L 2224/32225; H01L 2224/73265; H01L 2924/1434; H01L 2924/1431; H01L 2924/15747; H01L 2924/15788; H01L 2224/13147; H01L 2224/13644; H01L 2224/13655; H01L 2924/404

(57) ABSTRACT

One device includes a first chip having first electrodes on one surface, and a rough portion on another surface. The device also includes a second chip having second electrodes on one surface, and third electrodes electrically connected to the second electrodes and disposed on another surface, and stacked on the first chip so the third electrodes are electrically connected to the first electrodes. The device includes a resin layer covering the first and second chips so at least the other surface of the first chip and the one surface of the second chip are exposed. The device also includes a wiring board having connection pads formed on one surface, and stacked on the second chip so the connection pads are electrically connected to the second electrodes. The device includes a sealing resin portion formed on the wiring board to cover the first chip, the second chip, and the resin layer.

### TECHNICAL FIELD

The present invention relates to a semiconductor device and a method of manufacturing a semiconductor device.

### BACKGROUND

Increases in the speed and the level of functionality of electronic equipment have been accompanied by demands for semiconductor devices to become even more highly integrated. In recent years there has been widespread development of stacked-type semiconductor devices in which a plurality of semiconductor chips are stacked on one another, with the aim of increasing the degree of integration of semiconductor devices.

Patent literature article 1 discloses a CoC-type semiconductor device comprising molded resin formed in such a way as to cover a Si interposer, a plurality of DRAM chips and an interface chip which are stacked on a resin interposer.

However, the reverse surface of the interface chip, which constitutes the surface that is in contact with the molded resin, has a configuration in which bumps are not formed, and if the reverse surface of an interface chip that has been thinned by back grinding is provided with a mirror finish in order to increase the flexural strength of the interface chip, there is a risk that the strength of adhesion between the molded resin and the reverse surface of the interface chip will deteriorate. A deterioration in the strength of adhesion between the molded resin and the reverse surface of the interface chip leads to problems in that internal stresses in the sealing resin become concentrated at the corner portions of the reverse surface of the interface chip, and peeling occurs at the interface. As a result of this interfacial peeling, sites in the molded resin that have peeled expand and contract independently during temperature cycles, for example during reflow, and this contributes to the formation of package cracks, causing the reliability of the semiconductor device to deteriorate.

Meanwhile, patent literature article 2 discloses a technique in which unevenness is formed on an exposed reverse surface of a semiconductor chip which has been flip-chip mounted on a wiring board. More specifically, patent literature article 2 discloses a semiconductor device in which an uneven portion is provided on the reverse surface of a semiconductor chip in order to obtain a semiconductor device having good heat dissipation characteristics.

### PATENT LITERATURE

Patent literature article 1: Japanese Patent Kokai 2005-244143

Patent literature article 2: Japanese Patent Kokai 2010-182958

### SUMMARY OF THE INVENTION

### Problems to be Resolved by the Invention

However, in patent literature article 2 described hereinabove, although the uneven portion formed on the reverse surface of the semiconductor chip has a configuration in which oblique shapes are formed at the bottom side surfaces of the recessed portions, and at the end portions of the protruding portions, uneven portions are essentially not formed at the four corners of the semiconductor chip. There is thus a problem in that pressure applied to the end portions of the semiconductor chip, where internal stresses in the sealing resin become particularly concentrated, causes peeling to occur between the sealing resin and the semiconductor chip.

The present invention provides a semiconductor device in which a rough surface portion is provided in an end portion, at least, of a reverse surface of a semiconductor chip, and a method of manufacturing the same.

### Means of Overcoming the Problems

The present invention takes account of the problems discussed hereinabove, and one aspect thereof relates to a semiconductor device characterized in that it comprises: a first semiconductor chip on one surface of which a plurality of first bump electrodes are formed, and in which a rough surface portion is formed in at least an end portion of another surface opposing said one surface; a second semiconductor chip on one surface of which a plurality of second bump electrodes are formed, and in which a plurality of third bump electrodes, electrically connected to the plurality of second bump electrodes, are formed on another surface opposing said one surface, and which is stacked on the first semiconductor chip in such a way that the plurality of third bump electrodes are electrically connected to the plurality of first bump electrodes on the first semiconductor chip; a resin layer covering the first and second semiconductor chips in such a way that at least the other surface of the first semiconductor chip and the one surface of the second semiconductor chip are exposed; a wiring board on one surface of which a plurality of connection pads are formed, and which is stacked on the second semiconductor chip in such a way that the plurality of connection pads are electrically connected to the plurality of second bump electrodes; and a sealing resin portion formed on the wiring board in such a way as to cover the first semiconductor chip, the second semiconductor chip and the resin layer.

Another aspect of the present invention relates to a method of manufacturing a semiconductor device, characterized in that it comprises: a step of preparing a first semiconductor chip, on one surface of which a plurality of first bump electrodes are formed; a step of preparing a second semiconductor chip, on one surface of which a plurality of second bump electrodes are formed, and in which a plurality of third bump electrodes, electrically connected to the plurality of second bump electrodes, are formed on another surface opposing said one surface; a step of stacking the second semiconductor chip on the first semiconductor chip in such a way as to connect the plurality of third bump electrodes electrically to the plurality of first bump electrodes on the first semiconductor chip; a step of covering the first and second semiconductor chips with a resin layer in such a way as to expose at least the other surface of the first semiconductor chip and the one surface of the second semiconductor chip; a step of forming a rough surface portion in at least an end portion of another surface of the first semiconductor chip opposing the one surface; a step of stacking a wiring board, on one surface of which a plurality of connection pads are formed, on the second semiconductor chip in such a way that the plurality of connection pads are electrically connected to the plurality of second bump electrodes; and a step of forming a sealing resin portion on the wiring board in such a way as to cover the first semiconductor chip, the second semiconductor chip and the resin layer.

### Advantages of the Invention

The present invention makes it possible to reduce occurrences of peeling between the sealing resin and the semiconductor chip, and it is therefore possible to improve the reliability of the semiconductor device.

Other advantages of the present invention, and modes of embodiment thereof, will now be described in detail with reference to descriptions and drawings.

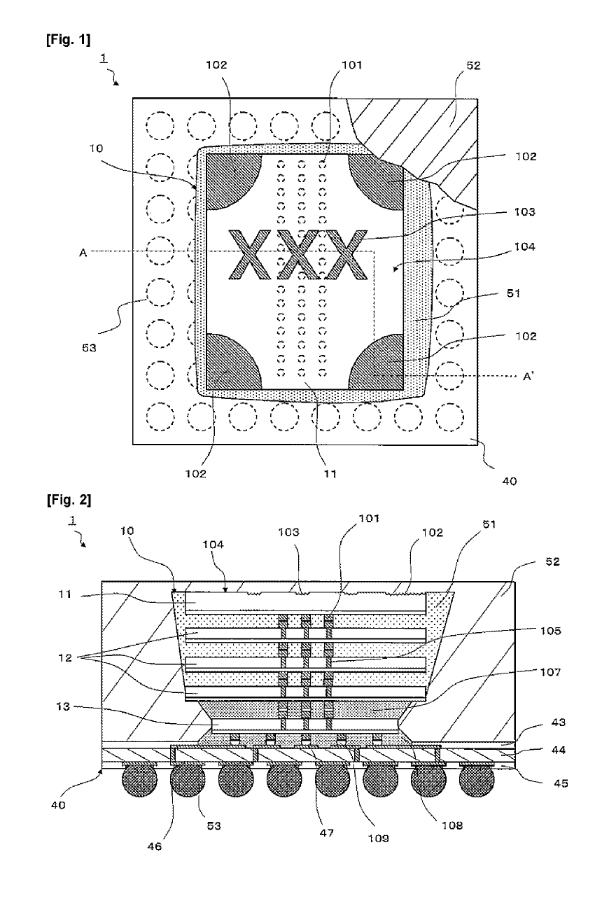

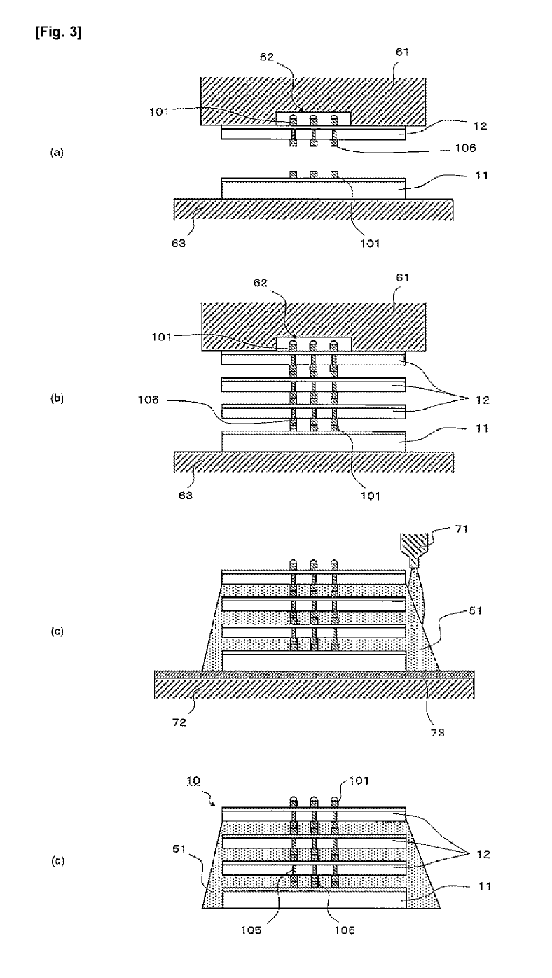

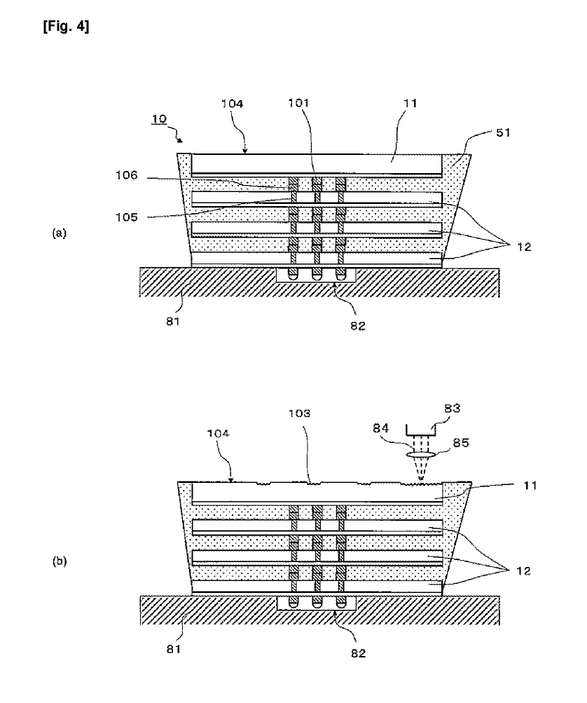

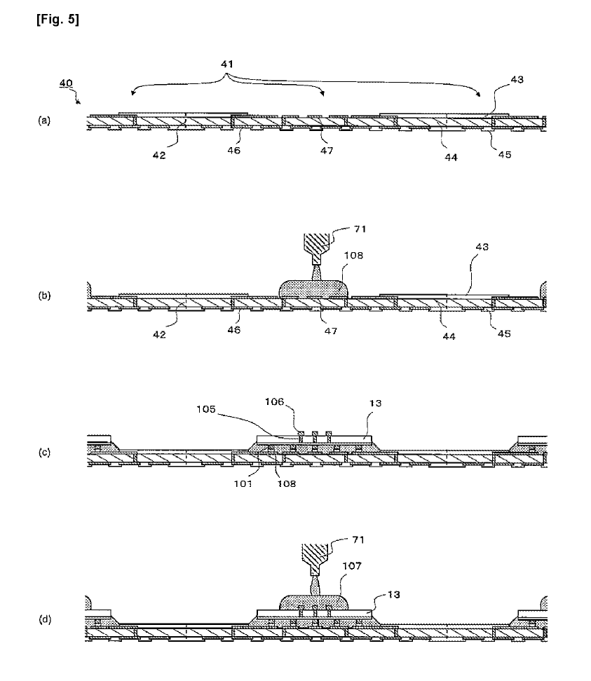

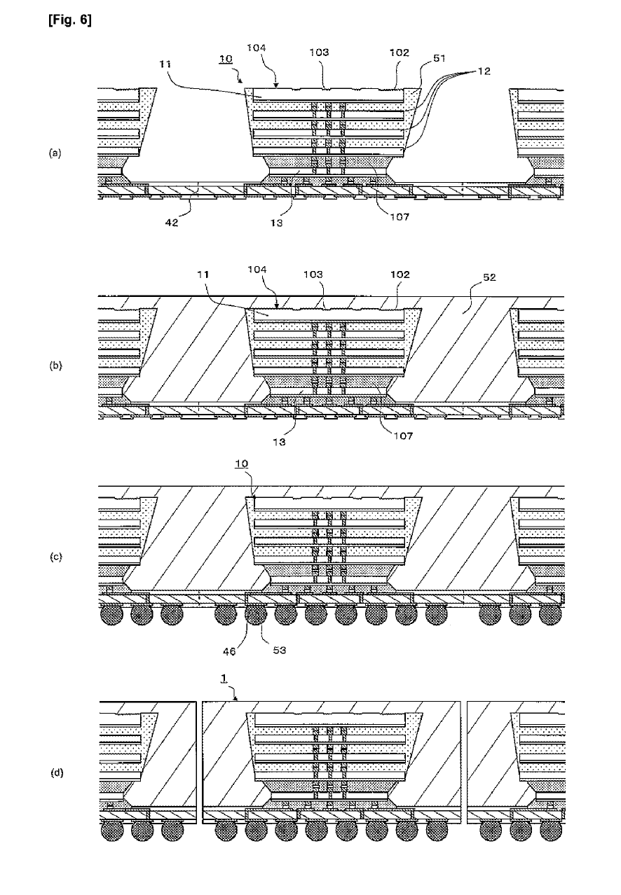

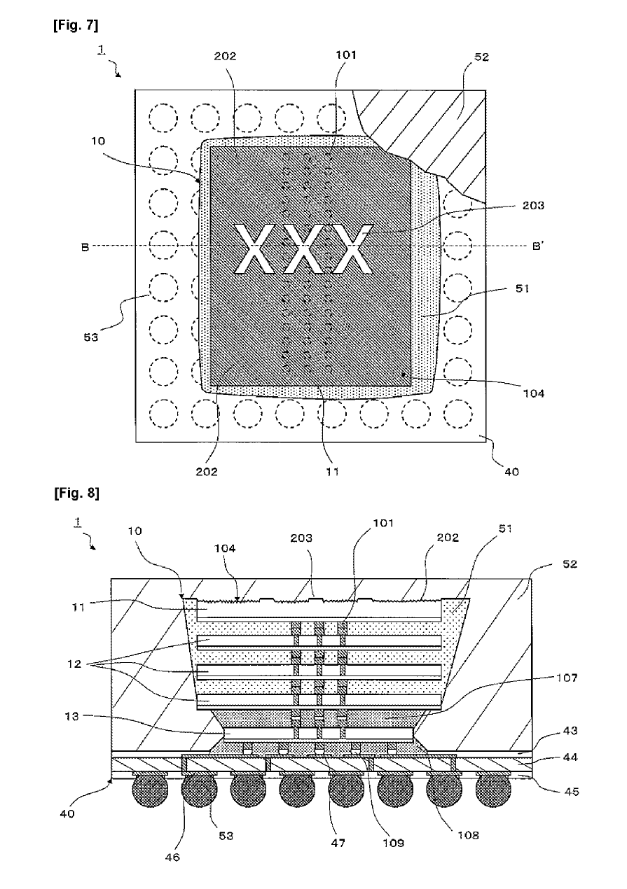

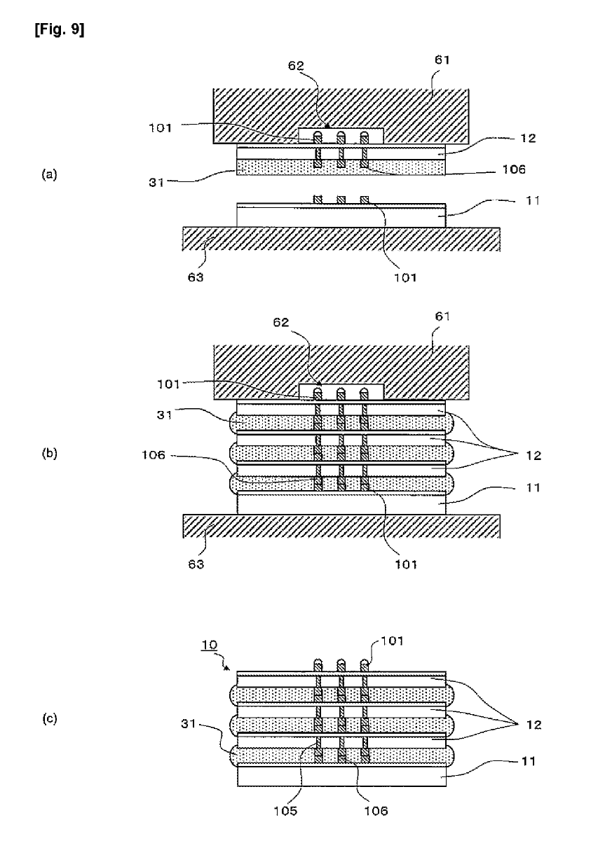

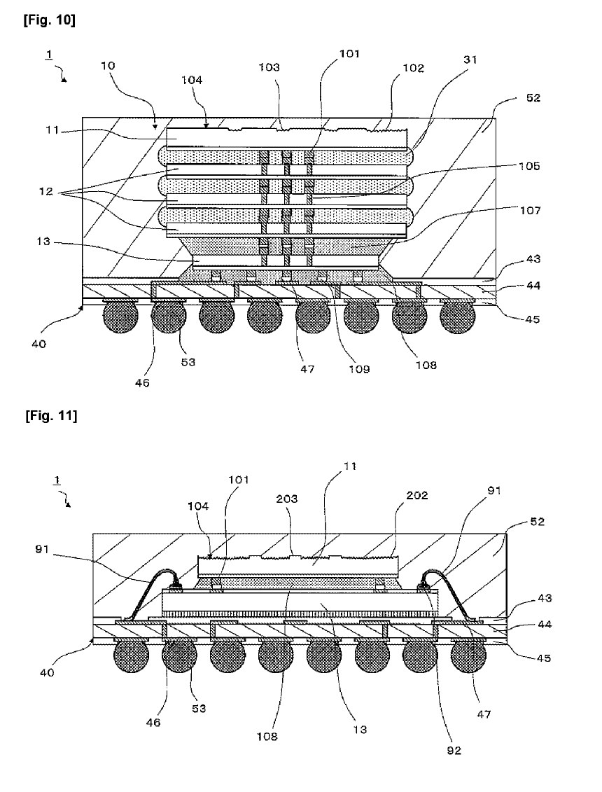

### BRIEF DESCRIPTION OF THE DRAWINGS

[FIG. 1] is a plan view illustrating the overall configuration of a semiconductor device according to a first exemplary embodiment of the present invention.

[FIG. 2] is a cross-sectional view of the semiconductor device illustrated in FIG. 1, through A-A′.

[FIG. 3] is a cross-sectional view used to describe a manufacturing process in which a chip stack is formed using memory chips.

[FIG. 4] is a cross-sectional view used to describe the manufacturing process in which a chip stack is formed using memory chips, following on from FIG. 3.

[FIG. 5] is a cross-sectional view used to describe a step in which a logic chip is installed on a wiring board on which the chip stack illustrated in FIG. 4 is to be mounted.

[FIG. 6] is a cross-sectional view used to describe a step in which the chip stack is mounted on the wiring board illustrated in FIG. 5.

[FIG. 7] is a plan view illustrating the overall configuration of a semiconductor device according to a second exemplary embodiment of the present invention.

[FIG. 8] is a cross-sectional view of the semiconductor device illustrated in FIG. 7, through B-B′.

[FIG. 9] is a cross-sectional view illustrating a modified example of a manufacturing process in which the chip stacks in the exemplary embodiments of the present invention are formed.

[FIG. 10] is a cross-sectional view used to describe a semiconductor device equipped with the chip stack illustrated in FIG. 9.

[FIG. 11] is a cross-sectional view illustrating a modified example of the semiconductor device in the exemplary embodiments of the present invention.

### MODES OF EMBODYING THE INVENTION

Modes of embodying the present invention will first be described.

A semiconductor device 1 in the present invention comprises: a wiring board 40; a first semiconductor chip 11 on one surface of which a plurality of bump electrodes 101 are formed, and in which a rough surface portion 102 is formed in at least the end portions (four corners) of another surface 104 opposing said one surface, and which is mounted on the wiring board 40 in such a way that said one surface faces the wiring board 40; and a sealing resin portion 52 formed in such a way as to cover at least the other surface 104 of the first semiconductor chip 11.

By forming the rough surface portions 102 in at least the four corners of said other surface 104 of the first semiconductor chip 11 disposed in a position furthest from the wiring board 40, and mounting said first semiconductor chip 11 on the wiring board 40 in such a way that said one surface faces the wiring board 40, adhesion between the sealing resin 52 and the reverse surface 104 of the first semiconductor chip 11 can be improved. In this way it is possible to reduce occurrences of peeling between the sealing resin 52 and the first semiconductor chip 11 at the corner portions of the reverse surface 104, where internal stresses in the sealing resin 52 become concentrated, and the reliability of the semiconductor device 1 can be improved.

An exemplary embodiment of the present invention will now be described with reference to the drawings. It goes without saying, however, that the technical scope of the present invention should not be interpreted as being in any way restricted by the exemplary embodiments described hereinafter.

### First Exemplary Embodiment

A first exemplary embodiment of the present invention will first be described. FIG. 1 is a plan view illustrating the overall configuration of the CoC-type semiconductor device 1 according to this exemplary embodiment. FIG. 2 is a cross-sectional view of the semiconductor device illustrated in FIG. 1, through A-A′.

The wiring board 40 comprises an insulating substrate 44 of glass epoxy or the like, and prescribed wiring line patterns comprising Cu or the like are formed on both surfaces of the insulating substrate 44. Insulating films 43 and 45 such as a solder resist film are formed on both surfaces of the insulating substrate 44, and prescribed opening portions are formed in the insulating films 43 and 45. Portions of the wiring line patterns are exposed in the opening portions, and sites exposed through the opening portions on one surface side form connection pads 47, and sites exposed through the opening portions on the other surface side form lands 46. A plurality of the connection pads 47 are disposed on said one surface of the wiring board 40, and a plurality of the lands 46 are disposed on the other surface. The lands 46 are disposed on said other surface in the shape of a grid array.

A semiconductor chip such as a logic chip 13 is mounted on one surface of the wiring board 40. In the logic chip 13, prescribed circuits and a plurality of electrode pads (which are not shown in the drawings) connected to said circuits are formed on one surface of a silicon substrate, and obverse surface bump electrodes 101 are formed on each of the plurality of electrode pads. The obverse surface bump electrodes 101 are formed in such a way as to project from said one surface of the logic chip 13, and comprise a pillar formed from Cu or the like, and a joining material 109 such as solder, formed on said pillar. The obverse surface bump electrodes 101 on the logic chip 13 are electrically connected to the connection pads 47 on the wiring board 40 by way of the joining material 109. Further, a plurality of reverse surface bump electrodes 106 are formed on the other surface of the logic chip 13. The reverse surface bump electrodes 106 are formed in such a way as to project from said other surface of the logic chip 13, and comprise a pillar formed from Cu or the like, and a plating layer such as Ni/Au formed on said pillar. Further, the logic chip 13 has a plurality of through-electrodes 105 which penetrate through the silicon substrate, and the plurality of reverse surface bump electrodes 106 are electrically connected to the corresponding obverse surface bump electrodes 101 by way of the corresponding through-electrodes 105. A gap is formed between the logic chip 13 and the wiring board 40, and this gap is filled with an underfill material 51 or an adhesive member (Non Conductive Paste) 107. It should be noted that the obverse surface bump electrodes 101 on the logic chip 13 are rewired by means of wiring lines on the obverse surface to match the pitch of the connection pads 47 on the wiring board 40, and are disposed with a pitch that is wider than the arrangement pitch of the reverse surface bump electrodes 106.

Further, a chip stack 10 formed by stacking a plurality of memory chips 11 and 12 on one another is stacked on the logic chip 13. The plurality of memory chips 11 and 12 are identically-sized semiconductor chips in which identical memory circuits are formed on one surface of a silicon substrate, for example, and the memory chips 11 and 12 each have a plurality of electrode pads (which are not shown in the drawings) which are connected to said circuits. Obverse surface bump electrodes 101 are formed on each of the plurality of electrode pads on the memory chips 11 and 12. The obverse surface bump electrodes 101 are formed in such a way as to project from the obverse surfaces of the memory chips 11 and 12, and comprise a pillar formed from Cu or the like, and a plating layer such as Ni/Au formed on said pillar. It should be noted that solder layers constituting a joining material, for example, are formed on the obverse surface bump electrodes 101 on the memory chip 12, from among the plurality of memory chips 11 and 12, that is adjacent to the logic chip 13, and said obverse surface bump electrodes 101 are joined to the reverse surface bump electrodes 106 on the logic chip 13 by way of the solder layer.

Further, a plurality of the reverse surface bump electrodes 106 are formed on the reverse surfaces of the three second memory chips 12, excluding the first memory chip 11 disposed in the position furthest from the wiring board 40. The reverse surface bump electrodes 106 are formed in such a way as to project from said other surface of the memory chip 12, and comprise a pillar formed from Cu or the like, and a joining member such as solder, formed on said pillar. The plurality of reverse surface bump electrodes 106 are each disposed in positions that overlap the corresponding obverse surface bump electrodes 101. Further, the second memory chips 12 have a plurality of through-electrodes 105 which penetrate through the silicon substrate, and the plurality of reverse surface bump electrodes 106 are electrically connected to the corresponding obverse surface bump electrodes 101 by way of the corresponding through-electrodes 105. The plurality of obverse surface bump electrodes 101 on the memory chips 11 and 12 are disposed in three rows in a central region of the substantially rectangular plate-shaped memory chips 11 and 12, along the long edges thereof, as illustrated in FIG. 1, for example.

The reverse surface bump electrodes 106 and the through-electrodes 105 are not formed in the first memory chip 11 disposed in a position furthest from the wiring board 40, and the thickness of said first memory chip 11 is greater than the thickness of the second semiconductor chips 12. For example, the thickness of the second semiconductor chips 12 is 50 μm, and the thickness of the first semiconductor chip 11 is 100 μm. By increasing the thickness of the first memory chip 11, furthest from the wiring board 40, and not forming the through-electrodes 105 therein, it is possible for the first memory chip 11, which is thick and has no through-electrodes 105, to bear the maximum stress resulting from expansion and contraction of the through-electrodes 105 in response to temperature variations during the manufacturing process, and occurrences of chip cracking can therefore be reduced.

Further, the chip stack 10 is covered with the underfill material 51 in such a way that the reverse surface 104 of the first semiconductor chip 11 and the obverse surface of the second memory chip 12 adjacent to the logic chip 13 are exposed, and the gaps between the memory chips 11 and 12 are filled with the underfill material 51.

Then, as illustrated in FIG. 1, the rough surface portions 102 are formed in prescribed zones in regions at the four corners of the reverse surface 104 of the first memory chip 11 in the chip stack 10 that is exposed away from the underfill material 51. The rough surface portions 102 are formed in a rough state, as illustrated in FIG. 2, by removing the mirror-finished surface using laser irradiation or the like.

Further, a mark portion 103 formed by laser marking is formed in a substantially central region of the reverse surface 104 of the first memory chip 11. Identification information such as a company name or a product name is formed in the mark portion 103. In this exemplary embodiment, a rough surface portion is also formed in the mark portion 103 by removing the surface using laser irradiation, and adhesion between the sealing resin 52 and the reverse surface 104 of the first memory chip 11 can thus also be improved by means of the mark portion 103 which comprises a rough surface portion.

Then the underfill material 51 or the adhesive member (NCP) 107 fills the gap between the logic chip 13 and the chip stack 10. Further, the sealing resin 52 is formed on one surface of the wiring board 40, and the logic chip 13 and the chip stack 10 are covered by the sealing resin 52.

In this exemplary embodiment, by forming the rough surface portions 102 in at least the four corners of said other surface of the first memory chip 11 disposed in a position furthest from the wiring board 40, adhesion between the sealing resin 52 and the reverse surface 104 of the first memory chip 11 can be improved through a resin anchoring effect. In this way it is possible to reduce occurrences of peeling between the sealing resin 52 and the first semiconductor chip 11 at the corner portions of the reverse surface 104, where internal stresses in the sealing resin 52 become concentrated, and the reliability of the semiconductor device 1 can be improved.

FIG. 3 is a cross-sectional view illustrating an example of a procedure for assembling the chip stack 10 employed in the semiconductor device 1 illustrated in FIG. 1 and FIG. 2. FIG. 4 is a cross-sectional view illustrating a step of forming the rough surface portions 102 and 103 on the chip stack 10, following on from FIG. 3.

When manufacturing the semiconductor device 1 in the first exemplary embodiment, first the plurality of semiconductor chips 11, 12 and 13 are prepared. The semiconductor chips 11, 12 and 13 have a configuration in which prescribed circuits such as memory circuits are formed on one surface of a plate-shaped semiconductor substrate comprising substantially rectangular Si or the like.

The semiconductor chip (first memory chip) 11 is placed on a bonding stage 63, illustrated in FIG. 3(a), with the one surface on which the prescribed circuits are formed, facing upward. A vacuum device, which is not shown in the drawings, vacuum-sucks the first memory chip 11 by way of suction holes provided in the bonding stage 63, thereby holding said memory chip 11 on the bonding stage 63.

The second-level semiconductor chip 12 is mounted on the first-level semiconductor chip 11, which is held on the bonding stage 63, and the second-level semiconductor chip 12 is connected and fixed onto the first-level semiconductor chip 11 by joining the obverse surface bump electrodes 101 on said one surface of the first-level semiconductor chip 11 to the reverse surface bump electrodes 106 on said other surface, on which circuits are not formed, of the second-level semiconductor chip 12.

Thermocompression bonding, in which a prescribed load is applied to the semiconductor chip 12 by a bonding tool 61 which is set to a high temperature (approximately 300° C., for example), as illustrated in FIG. 3 (b), may, for example, be used to join the bump electrodes 101 and 106 to one another. It should be noted that the semiconductor chips 11 and 12 may be joined to one another using not only thermocompression bonding, but also using ultrasonic bonding, in which pressure is applied while ultrasonic waves are applied, or using ultrasonic thermo-compression bonding in which these methods are combined.

The third-level semiconductor chip 12 is connected and fixed onto the second-level semiconductor chip 12 using the same procedure as that described hereinabove, and the fourth-level semiconductor chip 12 is connected and fixed onto the third-level semiconductor chip 12 using the same procedure as that described hereinabove (FIG. 3 (b)).

The plurality of semiconductor chips 11 and 12 which have been stacked on one another using the procedure described hereinabove are mounted on an application sheet 73 which is affixed to an application stage 72, as illustrated in FIG. 3 (c), for example. A material having poor wettability with respect to the underfill material 51, such as a fluorine-based sheet or a sheet or the like on which a silicone-based adhesive has been applied, is used as the application sheet 73. It should be noted that the application sheet 73 need not be affixed directly onto the application stage 72, and may be affixed anywhere, provided it is on a flat surface, for example it may be affixed onto a prescribed jig or the like placed on the application stage 72.

As illustrated in FIG. 3 (c), a dispenser 71 is used to supply the underfill material 51 to the plurality of semiconductor chips 11 and 12, which have been placed on the application sheet 73, from a location in the vicinity of the end portions thereof. Capillary action causes the supplied underfill material 51 to enter the gaps between the pairs of semiconductor chips 11 and 12, thereby filling the gaps between the semiconductor chips 11 and 12, while forming fillets at the periphery of the stacked plurality of semiconductor chips 11 and 12.

In this exemplary embodiment, a sheet comprising a material having poor wettability with respect to the underfill material 51 is used as the application sheet 73, and therefore spreading of the underfill material 51 is restricted, and the fillet width does not become large.

After the underfill material 51 has been supplied, the semiconductor chips 11 and 12, placed on the application sheet 73, are cured (heat treated) at a prescribed temperature, for example a temperature of approximately 150° C., thereby thermally curing the underfill material 51. This results in the formation of a first sealing resin layer comprising the underfill material 51 which covers the periphery of the chip stack 10 and fills the gaps between the semiconductor chips 11 and 12, as illustrated in FIG. 3 (d).

In this exemplary embodiment, a sheet comprising a material having poor wettability with respect to the underfill material 51 is used as the application sheet 73, and therefore the underfill material 51 is prevented from becoming attached to the application sheet 73 during the thermal curing.

After the underfill material 51 has been thermally cured, the chip stack 10 including said underfill material 51 is picked up from the application sheet 73. In this exemplary embodiment, a sheet comprising a material having poor wettability with respect to the underfill material 51 is used as the application sheet 73, and therefore the chip stack 10 can be picked up easily from the application sheet 73.

It should be noted that if the chip stack 10 becomes displaced when the underfill material 51 is being supplied to the chip stack 10, it is acceptable to secure the chip stack 10 provisionally to the application sheet 73 using a resin adhesive, and then to supply the underfill material 51.

The step of forming the rough surface portions 102 and the mark portion 103 on the semiconductor chip 11 in the semiconductor device 1 according to this exemplary embodiment will next be described with reference to FIG. 4. The rough surface portions 102 are formed on the reverse surface 104 of the first memory chip 11 of the chip stack 10 in a mark-forming step, together with the mark portion 103.

In the mark-forming step, the obverse surface side of the second memory chip 12 located at the opposite end to the first memory chip 11 is held by suction-attachment on a stage 81 of a laser marking device, in such a way that the reverse surface 104 of the first memory chip 11 faces upward, as illustrated in FIG. 4 (a). A bump clearance groove 82 is formed in the stage 81, corresponding to the arrangement of the obverse surface bump electrodes 101, and the obverse surface bump electrodes 101 on the second memory chip 12 are disposed in the bump clearance groove 82. The joining material such as solder for joining to the logic chip 13 is formed at the distal ends of the obverse surface bump electrodes 101 on the second memory chip 12, and by disposing the obverse surface bump electrodes 101 in the bump clearance groove 82, the chip stack 10 can be held without the shape of the joining material becoming deformed.

Then, as illustrated in FIG. 4 (b), laser light 84 from a light source 83 is condensed using a condensing lens 85 and is radiated at a prescribed position on the reverse surface 104 of the first memory chip 11 in the chip stack 10. Irradiation with the laser light 84 causes the mirror-finished surface to be removed, thereby forming the mark portion 103 and the rough surface portions 102 on the reverse surface 104 of the first memory chip 11. A YVO4 laser (yttrium vanadium oxide) or the like is used as the laser. The laser light 84 forms a desired identification mark (rough surface portion) 103 and the rough surface portions 102 at the four corners by being radiated through a mask having a prescribed pattern, or by being radiated in such a way as to draw a prescribed pattern.

By providing the desired mark portion 103 and the rough surface portions 102 in regions in the vicinity of the four corners on the reverse surface 104 of the first memory chip 11 in the chip stack 10, adhesion between the sealing resin 52 and the reverse surface 104 of the first memory chip 11, in particular in the vicinity of the four corners where stresses in the sealing resin 52 become concentrated, can be improved, and occurrences of peeling between the sealing resin 52 and the first memory chip 11 can be reduced. By reducing this peeling, occurrences of package cracking during temperature cycles, for example during reflow, can be reduced, and the reliability of the semiconductor device 1 can be improved. Further, by using laser marking to form the mark portion 103, which is formed on the reverse surface 104 of the first memory chip 11, the mark portion 103 also becomes a rough surface portion, and adhesion between the sealing resin 52 and the reverse surface 104 of the first memory chip 11 can be improved further.

Further, if the chip stack 10 is shipped alone rather than as the semiconductor device 1, then because the rough surface portions 102 can be formed on the four corners in combination with the step of forming the identification mark portion 103, which is formed on the chip stack 10, the rough surface portions 102 can be formed without the addition of a new process.

FIG. 5 is a cross-sectional view used to describe the steps whereby the semiconductor chip 13 is disposed on the wiring board 40, which is a constituent of the semiconductor chip 1 according to the first exemplary embodiment of the present invention. FIG. 6 is a cross-sectional view used to describe a step in which the chip stack 10 illustrated in FIG. 4 is mounted on the wiring board 40 illustrated in FIG. 5. It should be noted that FIG. 5 and FIG. 6 illustrate one example of an assembly procedure for forming a plurality of semiconductor devices 1 in one batch.

As illustrated in FIG. 5 (a), when assembling the semiconductor device 1, first a wiring board 40 provided with a plurality of product-forming regions 41 disposed in a matrix formation is prepared. The product-forming regions 41 are locations each of which will form the wiring board 40 of a semiconductor device 1, a prescribed pattern of wiring lines is formed on an insulating substrate 44 in each product-forming region 41, and each wiring line, except for the connection pads 47 and the lands 46, is covered by an insulating film 43 or 45 such as a solder resist film. Spaces between the product-forming portions 41 of the wiring board 40 serve as dicing lines 42 when the individual semiconductor devices 1 are cut apart.

A plurality of connection pads 47 for connecting to the chip stack 10 are formed on one surface of the wiring board 40, and a plurality of lands 46 for connecting solder balls 53, which serve as external terminals, are formed on the other surface. The connection pads 47 are connected to prescribed lands 46 by way of wiring lines.

When preparation of the wiring board 40 is complete, an insulating filler 108 such as NCP is applied using a dispenser 71 onto each product-forming region 41 in the wiring board 40, as illustrated in FIG. 5 (b).

Next, as illustrated in FIG. 5 (c), the connection pads 47 on the wiring board 40 are electrically joined to the obverse surface bump electrodes 101 on the logic chip 13 by way of the joining material 109. At this time, the filler 108 applied to the wiring board 40 fills the spaces between the wiring board 40 and the logic chips 13, adhesively fixing the wiring board 40 and the logic chips 13 together.

After the logic chips 13 have been adhesively fixed to the wiring board 40, the insulating adhesive member 107 such as NCP is applied using the dispenser 71 onto each logic chip 13 disposed on the wiring board 40, as illustrated in FIG. 5 (d).

The chip stacks 10 are next mounted on the logic chips 13 on the wiring board 40 (FIG. 6 (a)), and the obverse surface bump electrodes 101 on the chip stacks 11 are each joined to the reverse surface bump electrodes 106 on the logic chips 13 using thermocompression bonding, for example. At this time, the adhesive members 107 applied to the logic chips 13 fill the spaces between the chip stacks 10 and the logic chips 13, adhesively fixing the chip stacks 10 and the logic chips 13 together (FIG. 6 (a)).

The wiring board 40 on which the chip stacks 10 have been mounted is set in a molding die comprising an upper die and a lower die of a transfer molding device, which is not shown in the drawings, and the procedure moves to a molding step.

A cavity, which is not shown in the drawings, collectively covering a plurality of chip stacks 10, is formed in the upper die of the molding die, and the chip stacks 10 mounted on the wiring board 40 are accommodated in said cavity.

Next, the sealing resin 52 that has been melted by heating is injected into the cavity provided in the upper die of the molding die, and the cavity is filled with the sealing resin 52 in such a way as to entirely cover the chip stacks 10. A thermosetting resin such as an epoxy resin is used as the sealing resin 52.

Then, in a state in which the cavity is filled with the sealing resin 52, the sealing resin 52 is thermally cured by curing it at a prescribed temperature, for example approximately 180° C., to form the sealing resin 52 constituting a second sealing resin layer which collectively covers the chip stacks 10 mounted on the plurality of product-forming portions, as illustrated in FIG. 6 (b). Further, the sealing resin 52 is completely cured by baking it at a prescribed temperature.

In this exemplary embodiment, after the spaces between the semiconductor chips 11 and 12 in the chip stacks 10 have been sealed using the first sealing resin layer (underfill material) 51, the second sealing resin layer (sealing resin 52) is formed covering the entire chip stack 10, and it is therefore possible to suppress the generation of voids in the gaps between the semiconductor chips 11 and 12.

When the sealing resin 52 has been formed, the procedure moves to a ball mounting step in which, as illustrated in FIG. 6 (c), electrically conductive metal balls 22, such as the solder balls 53, which serve as external terminals of the semiconductor devices 1, are connected to the lands 46 formed on the other surface of the wiring board 40.

In the ball mounting step, the plurality of solder balls 53 are held by suction-attachment using a mounting tool, which is not shown in the drawings, provided with a plurality of suction-attachment holes, the positions of which coincide with the positions of the lands 46 on the wiring board 40, and after transferring flux to the solder balls 53, the held solder balls 53 are mounted in a batch onto the lands 46 of the wiring board 40.

After the solder balls 53 have been mounted on the lands 46 of all the product-forming regions 41, the wiring board 40 is subjected to reflow to connect the solder balls 53 to the lands 46.

When connection of the solder balls 53 is complete, the procedure moves to a board dicing step in which the individual product-forming regions 41 are separated from one another by cutting along prescribed dicing lines 42, to form the semiconductor devices 1.

In the board dicing step, the product-forming regions 41 are supported by bonding a dicing tape, which is not shown in the drawings, to the sealing resin layer 52. The product-forming regions 41 are then separated from one another by cutting at the prescribed dicing lines 42 using a dicing blade provided in a dicing device, which is not shown in the drawings, as illustrated in FIG. 6 (d). After separation by cutting, the CoC-type semiconductor device 1 illustrated in FIG. 1 is obtained by picking up the product-forming region 41 from the dicing tape.

According to this exemplary embodiment, the chip stack 10, in which the plurality of semiconductor chips 11 are stacked on one another, is produced first, after which said chip stack 10 is connected and fixed onto the wiring board 40 on which the logic chip 13 has been disposed, and it is therefore possible to reduce thermal stresses which are imparted, as a result of differences in the thermal expansion coefficient or the rigidity of the semiconductor chips and the wiring board 40, to the connecting portions between the semiconductor chips 11, 12, or to the semiconductor chips 11 and 12, during heat treatment during manufacture. It is therefore possible to suppress the occurrence of breaks in the connecting portions between the semiconductor chips 11 and 12, and the generation of cracks in the semiconductor chips 11 and 12.

Further, because the underfill material 51, which forms the first sealing resin layer, is supplied to the stacked plurality of semiconductor chips 11 and 12 on the application sheet 73 comprising a material having poor wettability with respect to the underfill material 51, the formation of the fillets formed from the underfill material 51 is stabilized, and the fillet width can be reduced. Increases in the size of the package are thus suppressed. Further, the chip stack 10 can be picked up easily from the application sheet 73 after the underfill material 51 has been supplied.

In this way, according to this exemplary embodiment, problems of peeling between the sealing resin 52 and the semiconductor chip 11 during reflow evaluation, for example, can be eliminated, and an improvement in the reliability of the semiconductor device 1 can be achieved.

Further, in this exemplary embodiment, by providing the logic chip 13 having functions that are different from those of the chip stack 10, it is possible to obtain a semiconductor device 1 provided with a larger memory capacity, or provided with more functions.

### Second Exemplary Embodiment

A second exemplary embodiment of the present invention will next be described in detail with reference to the drawings. In the same way as in the first exemplary embodiment, this exemplary embodiment relates to a semiconductor device 1 in which a chip stack 10 is mounted on a wiring board 40 on which a semiconductor chip 13 has been disposed, and which is subjected to a sealing process using sealing resin 52, and descriptions relating to these components are the same as in FIG. 1 and FIG. 2, and are therefore omitted here. The second exemplary embodiment differs from the semiconductor device 1 according to the first exemplary embodiment in that, on the reverse surface 104 of the first memory chip 11, the surface other than a mark portion 203 forms a rough surface portion 202.

FIG. 7 is a plan view illustrating the overall configuration of the semiconductor device 1 according to the second exemplary embodiment. FIG. 8 is a cross-sectional view illustrating the cross-sectional configuration of the semiconductor device illustrated in FIG. 7, through B-B′.

This exemplary embodiment is configured in the same way as the first exemplary embodiment, and differs from exemplary embodiment 1 in that it is configured in such a way that, as illustrated in FIG. 7, substantially the entire surface of the reverse surface 104 of the first memory chip 11, excluding a region which forms the mark portion 203, forms the rough surface portion 202, rather than only the four corners on the reverse surface 104 of the first memory chip 11.

As will be apparent from FIG. 8, the reverse surface 104 of the first memory chip 11 contains the rough surface portion 202, processed by radiating laser light 84, and the mark portion 203 having a mirror-finished surface. In the same way as in the first exemplary embodiment, the laser light 84 from the light source 83 is condensed using the condensing lens 85 and is radiated at a prescribed position on the reverse surface 104 of the first memory chip 11 in the chip stack 10. In this exemplary embodiment, the mark portion 203 which forms specific identification characters remains unmodified, and the laser light 84 is radiated onto the other parts. Irradiation with the laser light 84 causes the mirror-finished surface to be removed, thereby forming the rough surface portion 202 and the mark portion 203 on the reverse surface 104 of the first memory chip 11.

In this way, by providing the rough surface portion 202 by irradiating regions of the reverse surface 104 of the first memory chip 11 in the chip stack 10 other than the region which forms the mark portion 203, it is possible for adhesion between the sealing resin 52 and the reverse surface 104 of the first memory chip 11 to be improved further. As a result, occurrences of peeling between the sealing resin 52 and the first memory chip 11 can be reduced. By reducing this peeling, occurrences of package cracking during temperature cycles, for example during reflow, can be reduced, and the reliability of the semiconductor device 1 can be improved.

The same advantages as in the first exemplary embodiment can also be obtained in the second exemplary embodiment, in addition to which, by forming the rough surface portion 202 over substantially the entire reverse surface 104 of the first memory chip 11, rather than only in the four corner portions thereof, adhesion between the sealing resin 52 and the reverse surface 104 of the first memory chip 11 can be further improved.

FIG. 9 is a cross-sectional view illustrating a modified example of the semiconductor device 1 according to the exemplary embodiments described hereinabove. FIG. 10 is a cross-sectional view illustrating the overall configuration of the semiconductor device 1 assembled according to a modified example of the exemplary embodiments.

As illustrated in FIG. 9 (a), a resin layer 31, for example NFC, is provided in advance on the reverse surface of the second memory chip 12. As illustrated in FIG. 9 (b), stacking the second memory chips 12 on the first memory chip 11 causes the resin layer 31 to melt, and the resin layer 31 expands into the gaps between the semiconductor chips 11 and 12, filling said gaps. After filling, the resin layer 31 is hardened by curing at a prescribed temperature, to form the chip stack 10 as illustrated in FIG. 9 (c). It should be noted that the resin layer 31 contains a flux activator, for example, and thus the bump electrodes 101 and 106 can be connected together satisfactorily even after the resin layer 31 has been formed. In this way, by employing a configuration in which the resin layers 31 are provided in advance on the reverse surfaces of the second memory chips 12, and the gaps between the semiconductor chips 11 and 12 are filled by the resin layers 31 when the chips are stacked on one another, an underfill step becomes redundant, and the assembly cost can be reduced compared with the first exemplary embodiment. Further, by filling the gaps between the semiconductor chips 11 and 12 in the chip stacking stage using the resin layer 31, the processing efficiency can also be improved compared with a case in which the gaps are filled by employing capillary action in the underfill step. Then, by forming the rough surface portion 102 and the mark portion 103 on the reverse surface 104 of the first memory chip 11 and employing an assembly process, in the same way as in the first exemplary embodiment, the configuration of the semiconductor device 1 illustrated in FIG. 10 is achieved.

Further, in this modified example the same advantages as in the first exemplary embodiment are obtained by forming the rough surface portions 102 and 103 on the reverse surface 104 of the first memory chip 11, and in addition, because the resin layer 31 is disposed only between the semiconductor chips 11 and 12, stresses acting on the semiconductor chips 11 and 12 as a result of cure shrinkage of the resin layer 31 can be reduced, and reliability can be improved.

The invention devised by the inventors has been described hereinabove with reference to exemplary embodiments, but the present invention is not restricted to the abovementioned exemplary embodiments, and it goes without saying that various modifications are possible without deviating from the gist of the invention. For example, in the exemplary embodiments described hereinabove, descriptions were given of cases in which four of the same memory chips 11 and 12 are stacked on one another, but the chip stack may also be one in which different semiconductor chips are combined, for example memory chips 11 and 12 and logic chips 13. The configuration may also be one in which the number of stacked semiconductor chips is three or less, or five or more.

Further, in these exemplary embodiments, descriptions were given of cases in which the rough surface portions 102, 103 and 202 are formed on the reverse surface 104 of the semiconductor chip 11 in a position in the chip stack 10 furthest from the wiring board 40, but, as illustrated in FIG. 11, the configuration may also be such that the rough surface portion 202 is formed on the reverse surface 104 of a semiconductor chip 11 flip-chip stacked in a position furthest from the wiring board 40 in an MCP (Multi Chip Package).

The present invention can be implemented in various other forms, without deviating from the gist or the main features thereof. Thus in all respects, the modes of embodiment discussed hereinabove are no more than mere examples and should not be interpreted restrictively. The scope of the present invention is indicated by the scope of the patent claims, and is not constrained in any way by the specification text. Further, all variants, various improvements, substitutions and refinements belonging to a scope that is equivalent to the scope of the patent claims are included in the scope of the present invention.

This application is based upon and claims the benefit of priority from Japanese Patent Application No. 2013-97424, filed on May 7, 2013, the entire disclosure of which is incorporated herein by reference.

### EXPLANATION OF THE REFERENCE CODES

1 Semiconductor device
10 Chip stack
11 First memory chip (semiconductor chip)
12 Second memory chip (semiconductor chip)
13 Logic chip (semiconductor chip)
101 Obverse surface bump electrode
102 Rough surface portion
103 Mark portion (rough surface portion)
104 Reverse surface
105 Through-electrode
106 Reverse surface bump electrode
107 Adhesive member (NCP)
108 Filler (NCP)
109 Joining material
202 Rough surface portion
203 Mark portion
31 Resin layer (NCF)
40 Wiring board
41 Product-forming region
42 Dicing line
43 Insulating film (SR)
44 Insulating substrate
45 Insulating film (SR)
46 Land
47 Connection pad
51 Underfill material
52 Sealing resin
53 Solder ball
61 Bonding tool
62 Bump clearance groove
63 Bonding stage
71 Dispenser
72 Application stage
73 Application sheet
81 Stage
82 Bump clearance groove
83 Light source
84 Laser light
85 Condensing lens
91 Wire
92 Electrode pad

1. A semiconductor device comprising:
a first semiconductor chip on one surface of which a plurality of first bump electrodes are formed, and in which a rough surface portion is formed in at least an end portion of another surface opposing said one surface;
a second semiconductor chip on one surface of which a plurality of second bump electrodes are formed, and in which a plurality of third bump electrodes, electrically connected to the plurality of second bump electrodes, are formed on another surface opposing said one surface, and which is stacked on the first semiconductor chip in such a way that the plurality of third bump electrodes are electrically connected to the plurality of first bump electrodes on the first semiconductor chip;
a resin layer covering the first and second semiconductor chips in such a way that at least the other surface of the first semiconductor chip and the one surface of the second semiconductor chip are exposed;
a wiring board on one surface of which a plurality of connection pads are formed, and which is stacked on the second semiconductor chip in such a way that the plurality of connection pads are electrically connected to the plurality of second bump electrodes; and
a sealing resin portion formed on the wiring board in such a way as to cover the first semiconductor chip, the second semiconductor chip and the resin layer.

2. The semiconductor device as claimed in claim 1, wherein the rough surface portions are formed in the four corner regions of the other surface of the first semiconductor chip.

3. The semiconductor device as claimed in claim 1, wherein the rough surface portions include a mark portion for displaying identification information.

4. The semiconductor device as claimed in claim 1, wherein the rough surface portion is formed in a region other than a part forming a mark portion, on the other surface of the first semiconductor chip.

5. The semiconductor device as claimed in claim 1, wherein the resin layer is provided in advance on the second semiconductor chip.

6. A method of manufacturing a semiconductor device, comprising:
preparing a first semiconductor chip, on one surface of which a plurality of first bump electrodes are formed;
preparing a second semiconductor chip, on one surface of which a plurality of second bump electrodes are formed, and in which a plurality of third bump electrodes, electrically connected to the plurality of second bump electrodes, are formed on another surface opposing said one surface;
stacking the second semiconductor chip on the first semiconductor chip in such a way as to connect the plurality of third bump electrodes electrically to the plurality of first bump electrodes on the first semiconductor chip;
covering the first and second semiconductor chips with a resin layer in such a way as to expose at least the other surface of the first semiconductor chip and the one surface of the second semiconductor chip;
forming a rough surface portion in at least an end portion of another surface of the first semiconductor chip opposing the one surface;
stacking a wiring board, on one surface of which a plurality of connection pads are formed, on the second semiconductor chip in such a way that the plurality of connection pads are electrically connected to the plurality of second bump electrodes; and
forming a sealing resin portion on the wiring board in such a way as to cover the first semiconductor chip, the second semiconductor chip and the resin layer.

7. The method of manufacturing a semiconductor device as claimed in claim 6, wherein the rough surface portion formed on the other surface of the first semiconductor chip includes a mark portion, and said mark portion is formed in the same step as the step in which the rough surface portion is formed.

8. The method of manufacturing a semiconductor device as claimed in claim 6, wherein covering the first and second semiconductor chips with the resin layer comprises providing the resin layer in advance on the other surface of the second semiconductor chip, and by stacking the second semiconductor chip on the first semiconductor chip a gap between the chips is filled with the resin layer.
